(19) United States
(12) Patent Application Publication
(10) Pub. No.: US 2005/0118802 A1
(43) Pub. Date: Jun. 2, 2005

(54) Method for implementing poly pre-doping in deep sub-micron process

(76) Inventors: Chang-Sheng Tsao, Taipei (TW); Yi-Hang Chen, Hsin-Chu (TW); Jung-Hui Kao, Hsin-Chu (TW); Yen-Ming Chen, Hsin-Chu (TW); Pu-Fang Chen, Hsin-Chu (TW); Lin-June Wu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/991,839

(22) Filed: Nov. 18, 2004

Related U.S. Application Data
(60) Provisional application No. 60/526,432, filed on Dec. 2, 2003.

(51) Int. Cl. H01L 21/331

(52) U.S. Cl. 438/663

(57) ABSTRACT

Method for reducing dopant contamination during the fabrication of semiconductor devices is provided. The method includes doping a first layer, such as a polysilicon layer. During a subsequent annealing process, a gas, such as nitrogen, oxygen, a combination thereof, or the like, is introduced. The gas causes a cap layer to be formed over the first layer, preventing or reducing out-diffusing of the dopants and contamination of the process chamber. In a preferred embodiment, the gas is introduced during the ramp-up stage of the annealing process. The cap layer may be removed prior to etching the first layer.

### PRIORITY CLAIM

This application claims the benefit of U.S. Provisional Application No. 60/526,432, filed on Dec. 2, 2003, entitled “Method for Implementing Poly Pre-Doping in Deep Sub-Micron Process,” which is hereby incorporated herein by reference.

### TECHNICAL FIELD

The present invention relates generally to semiconductors, and more particularly, to a method of manufacturing semiconductor devices utilizing doped polysilicon structures.

### BACKGROUND

Semiconductor devices commonly include thin layers of conductive materials patterned to form specific devices, such as transistors, resistors, capacitors, and the like. In one technique, a thin layer of a semiconductor material is deposited and subsequently doped to alter the electrical characteristics of the material. Generally, doping is the process of implanting ions into the semiconductor layer and may be performed by an ion implant process wherein the semiconductor layer is bombarded with N-type or P-type ions or by an in situ process wherein ions are introduced as the semiconductor layer is being formed. Oftentimes, it is necessary to engineer the thickness of the semiconductor material and the amount/concentration of the doping to fabricate a device specifically suited for a particular function.

After the doping process, an annealing process is typically performed. When performing the annealing procedure, however, it has been found that ions may out-diffuse from the semiconductor layer and may contaminate the process chamber. In subsequent steps, the contaminated process chamber may adversely alter the electrical characteristics of other layers and structures. It has been found that the contamination may result in resistance and device shifts and may reduce the yield.

It has also been found that the amount of contamination may vary dependent upon the location of the wafer in the process chamber. For example, in one situation it has been found that the amount of resistance and device shift with wafers located in the bottom of the process chamber is worse than with wafers located in the top or center of the process chamber. Thus, even wafers within a single process run may exhibit different electrical characteristics.

Accordingly, there is a need for a method for fabricating semiconductor devices while preventing or reducing the amount of contamination that may occur during an annealing process.

### SUMMARY OF THE INVENTION

These and other problems are generally solved or circumvented, and technical advantages are generally achieved, by preferred embodiments of the present invention which provides method of manufacturing semiconductor devices utilizing doped polysilicon structures.

In accordance with an embodiment of the present invention, a method for reducing contamination of a wafer is provided. The method includes providing the wafer having a first layer formed thereon, doping the first layer with a first dopant, and annealing the wafer such that a first gas is introduced during the annealing process, the annealing causing a cap layer to be formed over the surface of the first layer, the cap layer reducing out-diffusing of dopant ions during the annealing.

In accordance with another embodiment of the present invention, a method for reducing contamination of a wafer is provided. The method includes providing the wafer having a first layer formed thereon, the first layer being doped with a first dopant, forming a cap layer over the first layer, and annealing the wafer, wherein the cap layer restricts out-diffusing of the first dopant during the annealing.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-section view of a wafer prepared with a semiconductor layer formed over the surface in accordance with an embodiment of the present invention;

FIG. 2 is a cross-section view of the wafer illustrated in FIG. 1 illustrating an ion implantation process in accordance with an embodiment of the present invention;

FIG. 3 is a cross-section view of the wafer illustrated in FIG. 2 after an anneal process has been performed creating a cap layer in accordance with an embodiment of the present invention;

FIG. 4 is a cross-section view of the wafer illustrated in FIG. 3 after the cap layer has been removed in accordance with an embodiment of the present invention; and

FIG. 5 is a cross-section view of the wafer illustrated in FIG. 4 after the semiconductor layer has been patterned in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to embodiments in a specific context, namely, pre-doping a polysilicon layer on a wafer with an N-type dopant. The invention may also be applied, however, to other designs and processes in which it is desirable to limit contamination (e.g., out-diffusing of ions) between process steps. For example, embodiments of the present invention may be used with materials other than polysilicon, different types of dopants (e.g., P-type dopants), different processes of doping, different ordering of process steps, and the like.

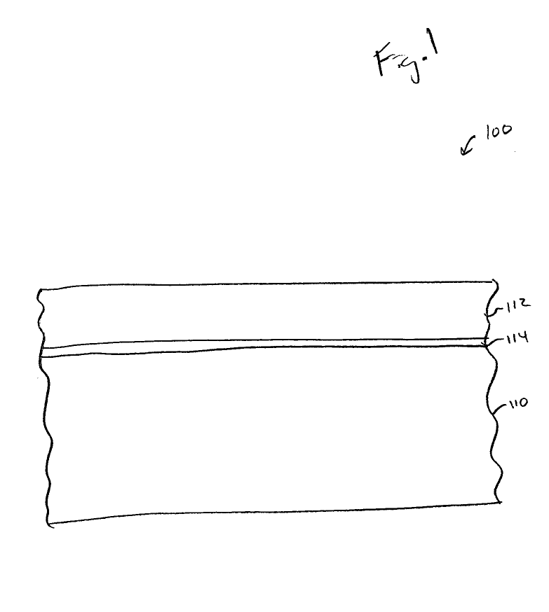

Referring now to FIG. 1, a cross-section view of a wafer 100 prepared with a semiconductor layer formed over the surface in accordance with an embodiment of the present invention is shown. The wafer 100 comprises a substrate 110 and a first layer 112. In an embodiment, the substrate 110 may be a silicon substrate, which is typically undoped, but may be lightly doped. Other materials, such as germanium, quartz, sapphire, glass, or the like could alternatively be used for the substrate 110. Alternatively, the substrate 110 may comprise an active layer of a semiconductor-on-insulator (SOI) substrate or a multi-layered structure such as a silicon-germanium layer formed on a bulk silicon layer.

The first layer 112 is formed of a material that is to be doped in a subsequent processing step. The first layer 112 is generally a semiconductor material such as polysilicon, amorphous silicon, or the like. In the preferred embodiment, polysilicon is deposited undoped by low-pressure chemical vapor deposition (LPCVD).

For illustrative purposes only, a gate dielectric layer 114 is also shown. The gate dielectric layer 114 with the first layer 112 formed thereon is a structure that may be formed during the fabrication of a transistor. The gate dielectric layer 114, which prevents electron depletion, may be an oxide layer (e.g., silicon dioxide) formed by any oxidation process, such as wet or dry thermal oxidation in an ambient comprising an oxide, H₂O, NO, or a combination thereof, or by chemical vapor deposition (CVD) techniques using is tetra-ethyl-ortho-silicate (TEOS) and oxygen as a precursor. In a typical application, the gate dielectric layer 114 is preferably about 15 Å to about 25 Å in thickness, but most preferably about 20 Å in thickness. Other thicknesses, thinner and thicker, may be used. When fabricating a gate electrode of a transistor, the thickness of the first layer 112 may be in the range of about 200 Å to about 5000 Å, but most preferably about 1500 Å. Other thicknesses may be used.

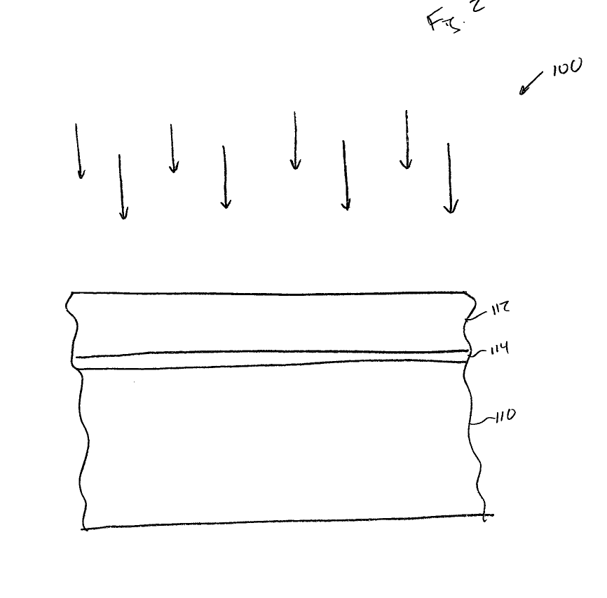

FIG. 2 is a cross-section view of the wafer 100 illustrated in FIG. 1 illustrating an ion implantation process in accordance with an embodiment of the present invention. In an embodiment in which the first layer 112 comprises a polysilicon material, the polysilicon may be doped with an N-type dopant, such as phosphorous, nitrogen, arsenic, antimony, or the like ions, to fabricate NMOS devices or with a P-type dopant, such as boron, aluminum, gallium, indium, and the like, to fabricate PMOS devices.

Optionally, first layer 112 may be patterned prior to pre-doping to restrict ion implantation to pre-determined areas of first layer 112. This may be useful, for example, if multiple devices are being formed that require varying levels of doping or varying types of doping (e.g., N-type doping, P-type doping, no doping, and the like). In this embodiment, one or more mask layers (not shown) may be utilized to selectively dope specific regions of the first layer 112.

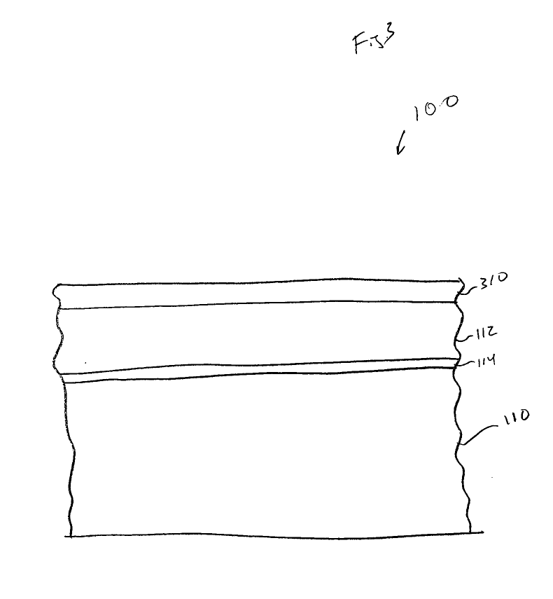

FIG. 3 is a cross-section view of the wafer 100 illustrated in FIG. 2 after an anneal process has been performed creating a cap layer 310 in accordance with an embodiment of the present invention. As discussed above, the ions may out-diffuse during an annealing process performed after the ion implant. The out-diffusing of the ions may contaminate the process chamber, which in turn may contaminate other wafers processed later. Thus, the cap layer 310 is formed of a material that provides a diffusion barrier without impacting device performance. Furthermore, it is preferred that the use of the cap layer 310 require little or no extra processing steps.

In an embodiment, the cap layer 310 may be an in situ formed cap, layer by introducing a gas during the annealing process. In an embodiment of the present invention, the gas may comprise oxygen, nitrogen, combinations thereof, or the like, preferably introduced during the ramp-up stage of the furnace anneal. The furnace anneal may be performed at a temperature of about 200° C. to about 1000° C. and for a time period of about 5 minutes to about 500 minutes. Preferably, however, the furnace anneal is performed at a temperature of about 750° C. for a time period of about 60 minutes. For a 90 nm generation design, the cap layer 310 may be formed by introducing oxygen at a concentration of about 1.0 slm and to a thickness about 10 Å to about 1000 Å, but more preferably about 100 Å to about 200 Å.

In an alternative embodiment, the cap layer 310 may be formed prior to the annealing process. In this alternative embodiment, the cap layer 310 may be a layer of Si₃N₄ formed by CVD techniques. This alternative embodiment, however, may incur additional process steps and decrease yields. Other materials may be used.

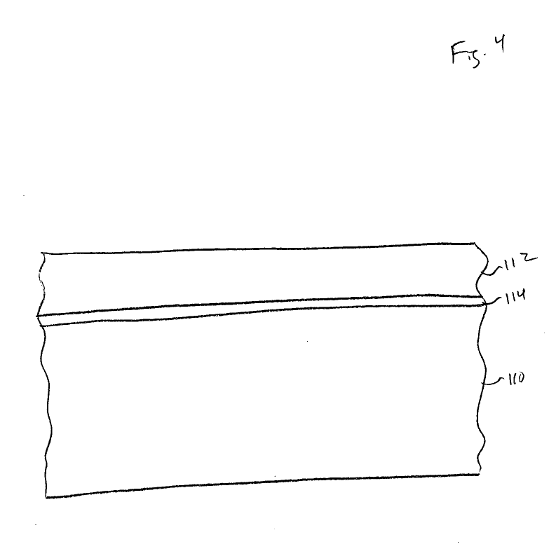

FIG. 4 is a cross-section view of the wafer illustrated in FIG. 3 after the cap layer 310 (FIG. 3) has been removed in accordance with an embodiment of the present invention. It is anticipated that the first layer 112 is to be patterned. One method of patterning the first layer 112 that may be used is by photolithography techniques as is known in the art. Photolithography techniques involve depositing a layer of photoresist material, irradiating (exposing) a portion of the photoresist material, and developing to remove a portion of the photoresist material. The remaining photoresist material protects the underlying material from subsequent processing steps, such as etching.

Because the cap layer 310 may affect subsequent etching steps, it may be desirable to remove the cap layer 310 prior to performing subsequent etching, or other process, steps. In the embodiment in which the cap layer 310 comprises an oxide film, e.g., silicon dioxide film, the cap layer 310 may be removed by a wet dip in a hydrofluoric acid after the annealing step is completed.

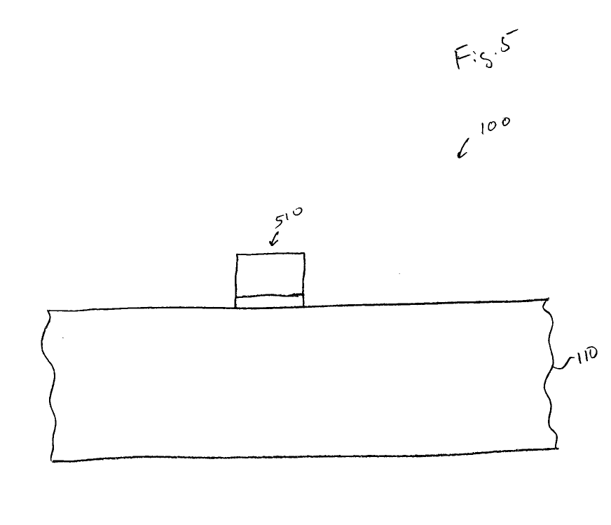

FIG. 5 is a cross-section view of the wafer illustrated in FIG. 4 after the first layer 112 (FIGS. 1-4) and the gate dielectric layer 114 have been patterned to form a gate electrode 510. The gate electrode 510 is shown for illustrative purposes only and other devices may be formed. Thereafter, standard processing techniques may be used to complete fabrication of the semiconductor device.

Although the present invention and its advantages have been described in detail, it should be understood that various changes, substitutions and alterations can be made herein without departing from the spirit and scope of the invention as defined by the appended claims. For example, different types of materials and processes may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for reducing contamination of a wafer, the method comprising:
providing the wafer having a first layer formed thereon;
doping the first layer with a first dopant; and
annealing the wafer such that a first gas is introduced during the annealing process, the annealing causing a cap layer to be formed over the surface of the first layer, the cap layer reducing out-diffusing of dopant ions during the annealing.

2. The method of claim 1, wherein the first layer comprises polysilicon.

3. The method of claim 1, wherein the first gas comprises oxygen, nitrogen, or a combination thereof.

4. The method of claim 1, wherein the cap layer comprises silicon dioxide.

5. The method of claim 1, wherein the cap layer is about 10 Å to about 1000 Å in thickness.

6. The method of claim 1, wherein the annealing is performed at 750° C. for about 60 minutes.

7. The method of claim 1, further comprising removing the cap layer after the annealing.

8. The method of claim 7, wherein the removing is performed by wet dipping the wafer in hydrofluoric acid.

9. The method of claim 1, wherein the first gas is introduced during the ramp-up stage of the annealing.

10. A method for reducing contamination of a wafer, the method comprising:
providing the wafer having a first layer formed thereon, the first layer being doped with a first dopant;
forming a cap layer over the first layer; and
annealing the wafer, wherein the cap layer restricts out-diffusing of the first dopant during the annealing.

11. The method of claim 10, wherein the forming is performed in the same process step as the annealing by introducing a first gas during the annealing.

12. The method of claim 11, wherein the first gas comprises oxygen, nitrogen, or a combination thereof.

13. The method of claim 11, wherein the first gas is introduced during the ramp-up stage of the annealing.

14. The method of claim 10, wherein the forming is performed prior to the annealing.

15. The method of claim 10, wherein the first layer comprises polysilicon.

16. The method of claim 10, wherein the cap layer comprises silicon dioxide.

17. The method of claim 10, wherein the cap layer is about 10 Å to about 1000 Å in thickness.

18. The method of claim 10, wherein the annealing is performed at 750° C. for about 60 minutes.

19. The method of claim 10, further comprising removing the cap layer after the annealing.

20. The method of claim 19, wherein the removing is performed by wet dipping the wafer in hydrofluoric acid.
